(19) United States
(12) Patent Application Publication
(10) Pub. No.: US 2026/0190258 A1
(43) Pub. Date: Jul. 2, 2026

(54) FOLDABLE DISPLAY APPARATUS FOR USE WITH AIRCRAFT IN-FLIGHT ENTERTAINMENT SYSTEM

(71) Applicant: Thales Avionics, Inc., Irvine, CA (US)

(72) Inventors: Jeffrey Everhart, Rural Hall, NC (US); Tudy Bedou, Irvine, CA (US); Ethan Trokie, Los Angeles, CA (US); Martin James, Whitesboro, TX (US)

(21) Appl. No.: 19/006,087

(22) Filed: Dec. 30, 2024

(51) Int. Cl. H05K 5/02; B64D 11/00

(52) U.S. Cl. CPC H05K 5/0234; B64D 11/00153

(57) ABSTRACT

A foldable display apparatus configured for use with an aircraft IFE system, includes a first portion having first front and back surfaces. The first front surface includes a first display screen. A second portion also is included and has second front and back surfaces. The second front surface includes a second display screen. The first and second portions are connected by a first joint configured to allow the foldable display apparatus to be moved from a folded configuration in which the first and second display screens are not exposed to an unfolded configuration in which the first and second display screens are exposed. At least one of a clamp, a magnet, and a metal, composite or plastic component is attached to at least a portion of the first back surface and configured to hold the first and second portions of the foldable display apparatus in the unfolded configuration.

### FIELD OF THE INVENTION

The present disclosure relates to foldable display apparatus configured for use with aircraft in-flight entertainment (IFE) systems.

### BACKGROUND

Today, it is common for both private and commercial passenger aircraft to have an IFE system. An IFE system generally includes an entertainment content source, such as a computer server having entertainment and/or information media (e.g., movies, music, television shows and/or other entertainment media content) stored in digital format; a wired or wireless networking system as needed to transmit the entertainment media throughout the aircraft; and at least one video display monitor to present the entertainment media to at least one passenger in his or her passenger accommodations. Each passenger may have his or her own personal video display monitor associated with his or her passenger accommodations to provide that passenger with entertainment and/or information.

Such aircraft cabin interiors with IFE systems may have space constraints. For example, passenger accommodations in an aircraft can impose a maximum size limitation on displays for passengers. Moreover, certification testing can include head injury criteria (HIC) relating to a passenger surviving impact with a display for an IFE having a seat back display. HIC criteria may be satisfied for a seat back display by, e.g., having a smaller protected screen on the display and including costly mechanisms to help reduce head injury upon impact.

### SUMMARY

Some embodiments of the present disclosure are directed to a foldable display apparatus configured for use with an aircraft in-flight entertainment system. The foldable display apparatus includes a first portion including a first front surface and a first back surface. The first front surface includes a first display screen. The foldable display apparatus further includes a second portion including a second front surface and a second back surface. The second front surface includes a second display screen. The first portion and the second portion are connected by a first joint configured to allow the foldable display apparatus to be moved from a folded configuration in which the first and second display screens are not exposed to an unfolded configuration in which the first and second display screens are exposed. The foldable display apparatus includes further includes at least one of a clamp, a magnet, and a metal, composite or plastic component attached to at least a portion of the first back surface and configured to hold the first portion and the second portion of the foldable display apparatus in the unfolded configuration.

As will be explained below with regard to some further embodiments, the foldable display apparatus can further include at least one additional third portion that includes a third front surface and a third back surface. The third front surface includes a third display screen. The at least one third portion is connected to the first portion or the second portion by a second joint configured to allow the foldable display apparatus to be moved from a folded configuration in which at least one of the first, second, and third display screens are not exposed to an unfolded configuration in which at least two of the first, second, and third display screens are exposed.

Other foldable display apparatus according to embodiments of the inventive subject matter will be or become apparent to one with skill in the art upon review of the following drawings and detailed description. It is intended that all such additional foldable display apparatus be included within this description, be within the scope of the present inventive subject matter, and be protected by the accompanying claims. Moreover, it is intended that all embodiments disclosed herein can be implemented separately or combined in any way and/or combination.

### BRIEF DESCRIPTION OF THE DRAWINGS

Other features of embodiments will be more readily understood from the following detailed description of specific embodiments thereof when read in conjunction with the accompanying drawings, in which:

FIG. 1 illustrates an aircraft fuselage containing an IFE system that provides entertainment services to passengers and includes a foldable display apparatus configured according to one or more embodiments of the present disclosure;

FIG. 2 is a block diagram illustrating the IFE system of FIG. 1 having elements that are configured to operate in accordance with some embodiments of the present disclosure;

FIG. 3 illustrates an example of a seat and a foldable display apparatus configured according to one or more embodiments of the present disclosure;

FIG. 4 illustrates an example of a view of the foldable display according to one or more embodiments of the present disclosure;

FIG. 5 illustrates a clamp of the foldable display apparatus according to one or more embodiments of the present disclosure;

FIG. 6 illustrates seat and foldable display apparatus with the foldable display apparatus deployed in a folded configuration according to one or more embodiments of the present disclosure;

FIGS. 7 and 8 illustrate seat and foldable display apparatus with the foldable display apparatus in folded and unfolded configurations according to one or more embodiments of the present disclosure;

FIG. 9 illustrates another example of a seat and a foldable display apparatus according to one or more embodiments of the present disclosure;

FIGS. 10A and 10B illustrate an example of movement and rotation of articulating arm according to one or more embodiments of the present disclosure;

FIGS. 11A and 11B illustrate another example of movement and rotation of articulating arm according to one or more embodiments of the present disclosure; and

FIG. 12 is a block diagram of elements of a foldable display apparatus configured to operate in accordance with some embodiments of the present disclosure.

### DETAILED DESCRIPTION

In the following detailed description, numerous specific details are set forth in order to provide a thorough understanding of embodiments of the present disclosure. However, it will be understood by those skilled in the art that the present invention may be practiced without these specific details. In other instances, well-known methods, procedures, components and circuits have not been described in detail so as not to obscure the present invention. It is intended that all embodiments disclosed herein can be implemented separately or combined in any way and/or combination.

Display size can be limited to what can be integrated in an aircraft seat which is driven by geometry of the seat. This human factor in seat design limits and influences the available geometry for an integrated display.

These geometric limitations typically may be used to have a fixed display. For example, if a seat can fit only an eleven inch display, the display size is eleven inches or less.

Moreover, HIC expresses the likelihood of a passenger developing a head injury from an impact with a structure inside an aircraft. Typically, IFE displays mounted on aircraft seat backs need to be designed to minimize the risk of head injuries to passengers. Regulations may require, for example, that where head contact with seat structure in an aircraft can occur, protection must be provided so that the head impact does not exceed a HIC value (e.g., 1,000 units). A seat back IFE display, therefore, typically needs to pass specific HIC testing standards set by aviation authorities such as the Federal Aviation Authority (FAA). Airlines, aircraft manufacturers, and aircraft seat manufacturers may spend millions of dollars, euros, pounds, etc. to show compliance with the regulations. A change to a seat back display for an IFE system, such as enlarging the display size, may require new HIC testing, which may be significant in terms of the testing, compliance, time, and cost.

In contrast, front row or center console displays connected to an arm, for example, are stowed during Taxi, Take-off, and Landing (TT & L) and therefore typically are not in a head strike zone for HIC. Such displays, however, may have other compliance criteria such as seat model compliance, pitch layout of passenger accommodations (LOPA) layout, etc.

Various embodiments of the present disclosure are directed to innovative foldable display apparatus for use with an aircraft IFE system which, when in a folded configuration or minimized position, stows within a constrained area in or adjacent to a seat, in a seat back, or on a bulkhead. Yet when the foldable display apparatus is deployed in an unfolded configuration, the display provides a larger viewing area than when stowed. Thus, the foldable display apparatus in its unfolded configuration can be much larger than an eleven inch display, for example, which may allow for better user interactions with the display given storage size constraints; yet still fit in a size constrained area designed for, e.g., an eleven inch display. Some embodiments of the foldable display apparatus also may help resolve possible issues with certification testing when a HIC value may require that a passenger survive impact with, e.g., a screen which may present challenges in passing certification testing.

As will be explained in further detail below, some embodiments are directed to a foldable display apparatus configured for use with an aircraft IFE system. The foldable display apparatus includes a first portion that includes a first front surface and a first back surface. The first front surface includes a first display screen. The foldable display apparatus further includes a second portion that includes a second front surface and a second back surface. The second front surface includes a second display screen. The first portion and the second portion are connected by a first joint configured to allow the foldable display apparatus to be moved from a folded configuration in which the first and second display screens are not exposed to an unfolded configuration in which the first and second display screens are exposed. The foldable display apparatus further includes at least one of a clamp, a magnet, and a metal, composite or plastic component attached to at least a portion of the first back surface and configured to hold the first portion and the second portion of the foldable display apparatus in the unfolded configuration.

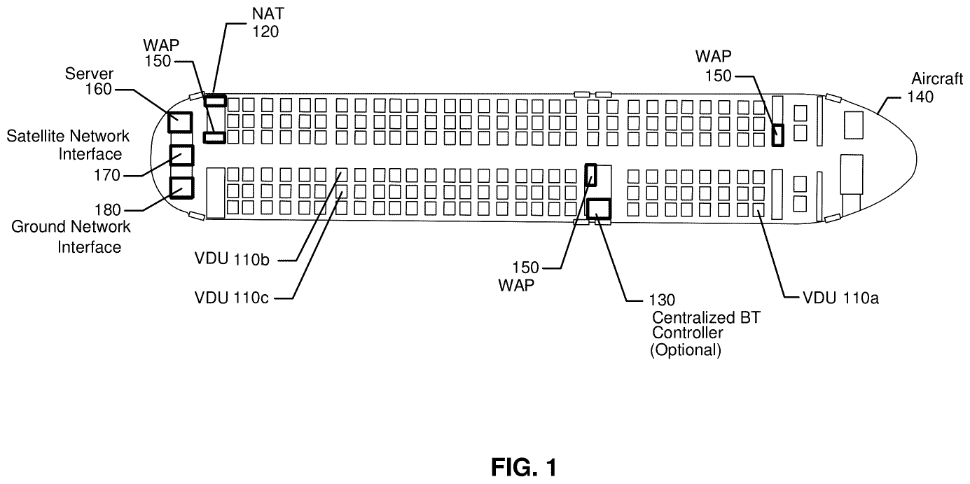

FIG. 1 illustrates an aircraft fuselage 140 containing an IFE system that provides entertainment services to passengers. The IFE system includes a content server 160 that streams and/or downloads electronic content through a wired network, e.g., Ethernet, and/or through WiFi radios within wireless access points (WAPs) 150 to other WiFi radios within video display units (VDUs) 110 mounted to structures in the aircraft, including to seat backs, seat armrests/frames, bulkheads, overhead structures, etc., and to WiFi radios within passenger devices carried on-board by passengers, such as smart phones, tablet computers, laptop computers, etc. For example, VDUs 110 may be seat back video display units (SVDUs) 110b, seat VDUs (e.g., in, adjacent to, or beneath a seat or seat arm) 110a, 110b, and/or bulkhead VDUs 110a (collectively referred to herein as VDU(s) 110).

The server 160 may be communicatively connected to the VDUs 110 through a wired data network (e.g., Ethernet cabling and electronic network interfaces) and/or a wireless data network. An example wireless data network is described in FIG. 1 includes a plurality of WAPs 150 that are installed (mounted) at spaced apart locations within the aircraft 140 fuselage to provide corresponding wireless communication cells. The WAPs 150 communicate through a wireless air interface that can be based on one or more communication protocols including, without limitation, any one or more of IEEE 802.11, WIMAX, Third Generation Partnership Project (3GPP) Long Term Evolution (LTE), fifth generation (5G), sixth generation (6G), etc.

Some or all of the seats of the aircraft 140 may be associated with a docking station may have a wired interface. A SVDU 110 facing the seat includes a processor that is connected to communicate through a Bluetooth transceiver and through the wired interface of the docking station. A PCU can include a processor connected to communicate through a wired interface and to communicate through a Bluetooth transceiver. The PCU may be configured to be releasably docked in the docking station to communicatively connect the wired interfaces of the PCU and the docking station. While docked in the docking station the processor of the PCU and the processor of the SVDU 110 are configured to communicate through the wired interfaces of the PCU and the docking station to establish a Bluetooth connection between the Bluetooth transceivers of the PCU and the SVDU 110. The processor of the PCU may be configured to not operate to establish the Bluetooth connection using communications through the Bluetooth transceiver of the PCU while docked in the docking station. Accordingly, a Bluetooth connection between a pair of Bluetooth transceivers in a PCU and a SVDU 110 can be established through wired communications via the docking station, and subsequent communications while the Bluetooth connection is maintained (e.g., unrelated to establishing the Bluetooth connection) are then performed through the Bluetooth transceivers.

Passengers may be provided internet services to VDUs 110 through aircraft based server 160. The server 160 may be communicatively connected to the VDUs 110 through a wired data network (e.g., Ethernet cabling and electronic network interfaces) and/or a wireless data network. An example wireless data network is described in FIG. 1 that includes a plurality of WAPs 150 that are installed (mounted) at spaced apart locations within the aircraft 140 fuselage to provide corresponding wireless communication cells. The WAPs 150 communicate through a wireless air interface that can be based on one or more communication protocols including, without limitation, any one or more of IEEE 802.11, WIMAX, 3GPP Long Term Evolution (LTE), 5G, 6G, etc.

The system in the example in FIG. 1 includes a central Bluetooth connection controller 130 that is communicatively connected to the VDUs 110 through a wired network, such as Ethernet, and/or through the WAPs 150 via a wireless network such as WiFi 802.11. The central Bluetooth connection controller 130 is configured to control setup, maintenance, and/or termination of Bluetooth connections between the VDUs 110c and the PCUs.

The aircraft 140 may also include a satellite link interface 170 that is configured to provide wireless data communications through a satellite communication system and/or through direct aircraft-to-ground communication links. The satellite data link interface 170 may be any satellite connectivity system that provides data communications capabilities for aircraft within range of satellite based communications network equipment, using radio transceiver circuits located onboard the aircraft. The wireless communications may be performed using IEEE 802.11, WIMAX, and/or 3GPP LTE technologies, etc. A communication link can be established, for example, between the aircraft based server 160 and a ground based server via the satellite network.

The aircraft 140 may also include a ground network link interface 180 that is configured to provide wireless data communications through a ground communication system and/or through direct aircraft-to-ground communication links. The ground data link interface 180 may be a radio frequency (RF) interface that provides data communications capabilities for aircraft within range of ground based communications network equipment, using radio transceiver circuits located onboard the aircraft. The wireless communications may be performed using IEEE 802.11, WIMAX, and/or 3GPP LTE technologies, etc. A communication link can be established, for example, between the aircraft based server 160 and a ground based server via the ground network.

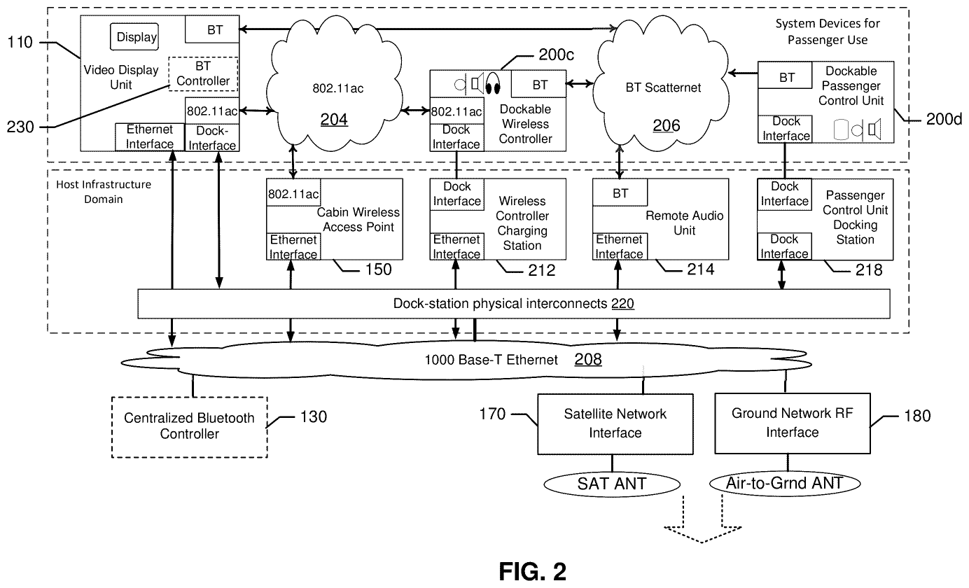

FIG. 2 is a block diagram of the IFE system of FIG. 1 having elements that are configured to operate in accordance with some embodiments of the present disclosure. Referring to FIG. 2, the IFE system includes system devices that can be located at each passenger seat location, and which is configured to communicate with various types of user devices that can be provided by the airline and/or carried on-board by passengers. The seat-located system devices can communicate using RF resources within the ISM band with the PCUs using a Bluetooth (BT) scatternet wireless network 206 and may use an IEEE 802.11ac wireless network 204.

The system devices can include a VDU 110, a dockable wireless controller 200c, and a dockable PCU 200d. The system may include only one or both of the dockable wireless controller 200c and the dockable passenger control unit 200d, which may be the same or similar type of device or may be different types of devices, and which can be collectively referred to as wireless controllers. The dockable wireless controller 200c and the dockable PCU 200d can be operated by a passenger to wirelessly control the VDU 110, such as to select internet content that is consumed (e.g., played through a foldable display apparatus), select among menu items, and control other operations of the VDU 110. Audio content may be streamed through the Bluetooth connection from the VDU 110 to a user device, e.g., Bluetooth headphones. Pictures, video, textual information, and/or commands may be communicated from the VDU 110 to a user device through the Bluetooth connection.

The VDU 110 can be a foldable display apparatus. The foldable display apparatus can include video display circuitry, a general-purpose processor, a Bluetooth transceiver, and an Ethernet interface or other wired network interface. A dockable wireless controller 200c may be used with VDU 110. The dockable wireless controller includes a general-purpose processor, a Bluetooth transceiver, and a dock wired interface, and may include display circuitry connected to a foldable display device, and audio decoding circuitry connected to a wired headphone jack and/or the Bluetooth transceiver for wireless communication with a passenger's wireless headset. The dockable PCU 200d can similarly include a general-purpose processor, a Bluetooth transceiver, and a dock wired interface, and may include display circuitry connected to a foldable display apparatus, and audio decoding circuitry connected to a wired headphone jack and/or the Bluetooth transceiver for wireless communication with a passenger's wireless headset. The wireless controller 200c, the passenger control unit 200d and dockable passenger control unit 200d, collectively referred to as wireless controller 200, may be configured as handheld devices for operation by passengers and can be stored in docking stations, which may be configured to recharge batteries within the handheld devices. A wireless controller 200 may be a handheld device that is owned by the aircraft operator and provided for temporary use by a passenger during a flight, or may be a PED carried on-board by passengers, such as mobile phones, tablet computers, laptop computers, wireless headphones, etc.

The VDUs 110 and seat-located system devices are connected to host infrastructure that can include the cabin WAPs 150 spaced apart within the aircraft cabin and mounted to cabin ceiling structures, storage bin structures, bulkheads, etc. An Ethernet backbone network 208, e.g., 1000 Base-T Ethernet, extends throughout the aircraft cabin to communicatively interconnect the seat-located system devices to the server 160 and the WAPs 150. The WAPs 150 can each include an 802.11ac or other WiFi transceiver and an Ethernet interface that connects to the Ethernet backbone network 208.

The host infrastructure can include a PCU docking station 218, a wireless controller charging station 212 (although its functionality may be incorporated into the docking station 218), and a remote audio unit 214. The wireless controller charging station 212 may be located at each seat and have a dock interface that releasably stores the dockable wireless controller 200c and charges a battery therein, and has an Ethernet interface that connects to the Ethernet backbone network 208. The PCU docking station 218 may also be located at each seat and have a dock interface that releasably stores the dockable PCU 200d and charges a battery therein, and has an Ethernet interface that connects to the Ethernet backbone network 208.

The VDUs 110 configured to face a seat, at least when deployed, respectively can include a processor that is connected to communicate through a Bluetooth transceiver and through the wired interface of the docking station 218. A wireless controller (PCU) 200 includes a processor connected to communicate through a wired interface and a Bluetooth transceiver. The wireless controller 200 is configured to be releasably docked in the docking station 218 to communicatively connect the wired interfaces of the wireless controller 200 and the docking station 218. While docked in the docking station 218 the processor of the wireless controller 218 and the processor of the display unit 110 may be configured to communicate through the wired interfaces of the wireless controller 200 and the docking station 218, via a dock-station physical interconnects (e.g., wired connections) 220, to establish a Bluetooth connection between the Bluetooth transceivers of the wireless controller 200 and the VDU 110. The processor of the wireless controller 200 may be configured to not operate to establish the Bluetooth connection using communications through the Bluetooth transceiver of the wireless controller 200. Accordingly, a Bluetooth connection between a pair of Bluetooth transceivers in a wireless controller 200 and a VDU 110 is established through wired communications and subsequent communications while the Bluetooth connection is maintained are then performed through the Bluetooth transceivers.

The system further includes the central Bluetooth controller 220 that is communicatively connected to the VDUs 110 through the Ethernet backbone network 208 and/or through the WiFi 802.11 network 204.

The remote audio unit 214 may be located at each seat or adjacent to a group of seats, and can contain a wired headphone jack, a Bluetooth transceiver, and an Ethernet interface that connects to the Ethernet backbone network 208, to receive and play audio through a loudspeaker and/or through the Bluetooth transceiver and/or the wired headphone jack to a headset worn by one or more passengers.

In accordance with present embodiments, the VDUs 110 may include a foldable display apparatus that includes at least one of a clamp, a magnet, and a metal component attached to at least a portion of the first back surface and configured to hold the first portion and the second portion of the foldable display apparatus in the unfolded configuration.

In an example implementation, each seat may include or be associated with a video arm (e.g., a mechanical deployment arm) used to deploy, position and/or support the particular VDU 110 associated with that seat so that the entertainment and/or information displayed on the VDU 110 can be more easily viewed by the passenger associated with that seat. The video arm can allow the VDU 110, when not in use, to be stowed securely under a seat, between seats, or inside a seat console associated with one or more seats, for example. The video arm may also allow the VDU 110 to be deployed from a stowed position and positioned in front of the particular passenger associated with that video display monitor in a deployed position.

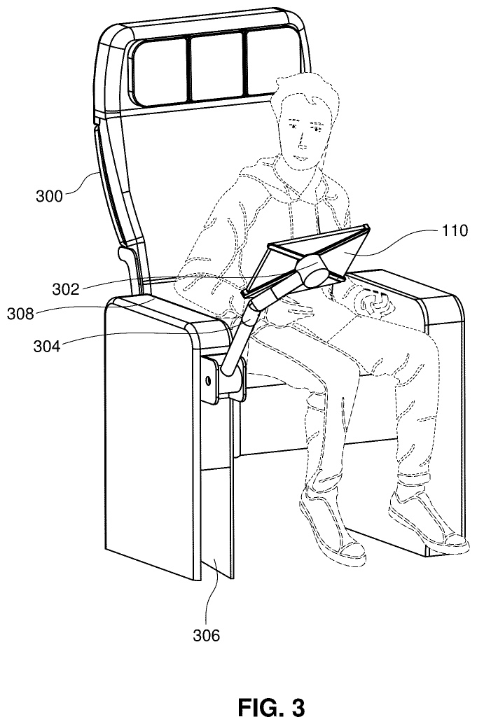

FIG. 3 illustrates an example of a seat 300 and a foldable display apparatus 110 shown in a deployed and folded configuration for a front row seat, for example. In this example, foldable display apparatus 110 includes a clamp 302. Clamp 302 is connected to the foldable display apparatus 110 and to an articulating arm 304. In this example, the articulating arm 304 also is connected to structure of seat 300 in the aircraft. Articulating arm 304 is configured to articulate movement during deployment of foldable display apparatus 110 from storage, and during storage of the foldable display apparatus 110. Articulating arm 304 guides movement of the foldable display apparatus 110 to become aligned with and enter a video storage compartment 306 within or underneath an arm 308 of seat 300 for storage, and to deploy the foldable display apparatus 110 from video storage compartment 306.

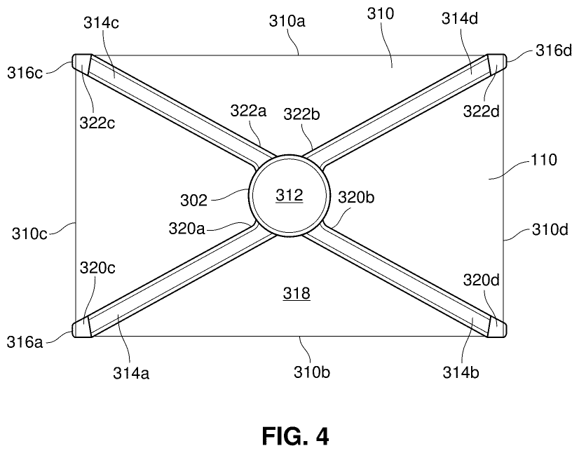

FIG. 4 illustrates an example of a view of the foldable display 110 connected to clamp 302. For ease of reference, in FIG. 4, articulating arm 304 is not shown in order to show hub 312 of clamp 302. The foldable display apparatus 110 includes a first portion 310 that includes a top edge 310a, a bottom edge 310b opposite the tope edge 310a, a first side edge 310c, and a second side edge 310d opposite the first side edge 310c. Clamp 302 includes hub 312. Hub 312 also connects to articulating arm 304 (not shown). Hub 312 includes a first arm 314a, a second arm 314b, a third arm 314c, and a fourth arm 314d that respectively extend from hub 312. The first arm 314a and the second arm 314b respectively are configured to attach to at least a portion of the bottom edge 310b. The third arm 314c and the fourth arm 314d are configured to attach to at least a portion of the first side edge 310c and the second side edge 310d, respectively, to allow the top edge 310a to pivot.

An alternative exploded view of clamp 302 is illustrated in the example in FIG. 5. In this alternative, the hub has two portions 312a and 312b. Hub portion 312a includes a first arm and a second arm, e.g. first arm 314a and a fourth arm 314d, that respectively extend from hub portion 312a. Hub portion 312b includes a third arm and a fourth arm, e.g. second arm 314b and a third arm 314c, that respectively extend from hub portion 312b. Hub portion 312a and hub portion 312b are connected with at least one connector 316, e.g., a screw. Additionally or alternatively, hub 312, or a hub portion 312a,312b can include different or additional connectors, such as a clutch/brake 324 and/or a tab 326.

Accordingly, in some embodiments, the clamp includes a hub having two portions. The two portions include (i) a first hub portion including a first arm and a second arm that respectively extend from the first hub portion, (ii) a second hub portion including a third arm and a fourth arm that respectively extend from the second hub portion, and (iii) the first hub portion and the second hub portion are connected with at least one connector.

Other examples include a foldable display apparatus 110 connected to a seat back (e.g., seat back 700 shown in FIG. 7) or a center console (e.g., between two seats 300).. For a seat back implementation, the foldable display may be connected to a clamp 302, clutch 324, and/or magnet (e.g., magnet 900, 902). The clamp 302, clutch 324, and/or magnet 900, 902 can attach to a fixed or tilt bracket in the seat back 700, for example. In such an implementation, the foldable display 110 can rotate and can be unfolded for a larger size as discussed herein.

For a center console implementation, the foldable display 110 can be connected to an arm (e.g., an articulating arm 304) via a clamp 302, clutch 324, and/or magnet 900, 902, and the arm 304 can be moved to deploy the foldable display 110 from a storage compartment in the center console. Further, the arm 304 can be moved to store the foldable display 110 in the storage compartment in the center console. In such an implementation, the foldable display 110 also can rotate and can be unfolded for a larger size when deployed as discussed herein.

As discussed herein, hub 312 can be connected to articulating arm 304 mounted in an aircraft.

Accordingly, in some embodiments, the hub is connected to an articulating arm mounted in an aircraft.

As shown in FIG. 4, the foldable display apparatus 110 can be connected to clamp 302. First portion 310 of foldable display apparatus 110 includes a first corner 316a, a second corner 316b, a third corner 316c, and a fourth corner 316d. Clamp 302 includes hub 312. Hub 312 includes first arm 314a, second arm 314b, third arm 314c, and fourth arm 314d that respectively extend from hub 312. First arm 314a and second arm 314b, respectively, include a first end 320a, 320b connected to hub 312 and a second end 320c, 320d configured to respectively engage (i) the first corner 316a and a first portion of the first back surface 318, and (ii) the second corner 320b and a second portion of the first back surface 318. The third arm 314c and the fourth arm 314d, respectively, include a first end 322a, 322b connected to the hub 312 and a second end 322c, 322d configured to respectively engage (i) a side edge of the third corner 316c and a first portion of the first back surface 318, and (ii) a side edge of the fourth corner 316d and a second portion of the first back surface 318.

Accordingly, in some embodiments, the first portion includes a first corner, a second corner, a third corner and a fourth corner. The clamp includes a hub and a first arm, a second arm, a third arm, and a fourth arm that respectively extend from the hub. The first arm and the second arm, respectively, include a first end connected to the hub and a second end configured to respectively engage (i) the first corner and a first portion of the first back surface, and (ii) the second corner and a second portion of the first back surface. The third arm and the fourth arm, respectively, include a first end connected to the hub and a second end configured to respectively engage (i) a side edge of the third corner and a first portion of the first back surface, and (ii) a side edge of the fourth corner and a second portion of the first back surface.

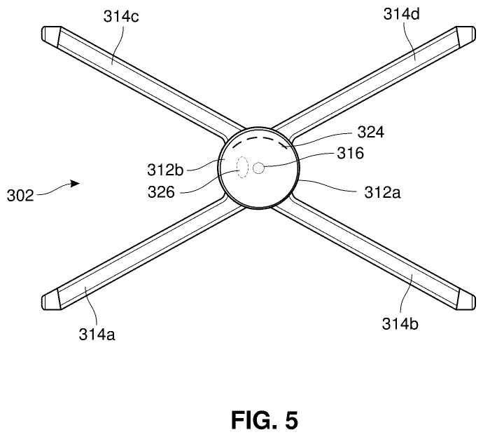

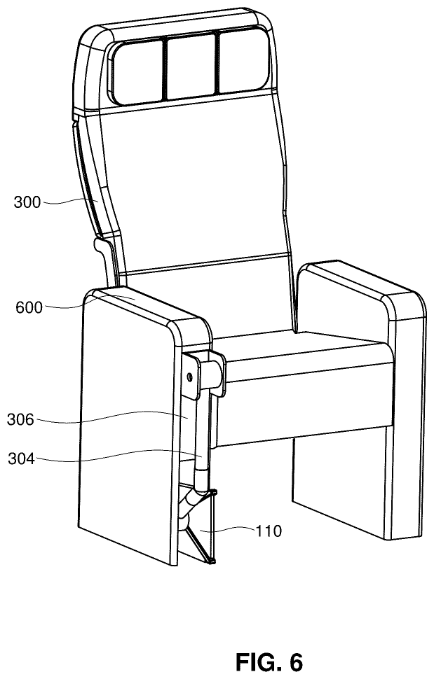

FIG. 6 illustrates seat 300 and foldable display apparatus 110 with the foldable display apparatus 110 deployed in a folded configuration. As shown, articulating arm 304 is configured to articulate movement during deployment of the foldable display apparatus 110 to guide movement of the foldable display apparatus 110 to exit the video storage compartment 306 within or underneath an arm 600 of seat 300 for storage.

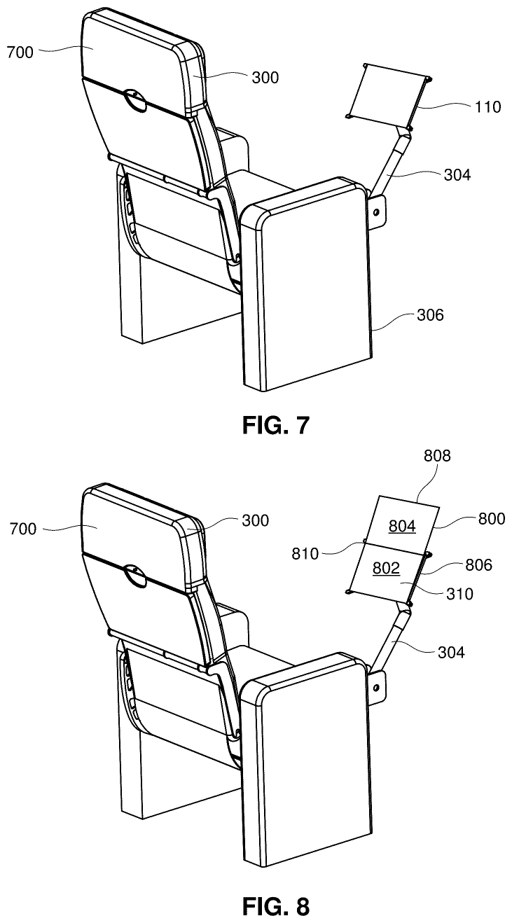

FIGS. 7 and 8 illustrate seat 300 and foldable display apparatus 110 with the foldable display apparatus 110 in folded (FIG. 7) and unfolded configurations (FIG. 8). As shown, in FIG. 8, foldable display apparatus 110 includes a first portion 310 and a second portion 800. First portion 310 includes first front surface 802 and first back surface 806. First front surface 802 includes a first display screen. Second portion 800 includes second front surface 804 and second back surface 808. Second front surface 804 includes a second display screen. The first portion 310 and the second portion 800 are connected by a first joint 810 configured to allow the foldable display apparatus 110 to be moved from the folded configuration shown in FIG. 7 in which the first and second display screens are not exposed to an unfolded configuration shown in FIG. 8 in which the first and second display screens are exposed.

Further, as shown in FIGS. 4, 7 and 8, first portion 310 includes top edge 310a, bottom edge 310b opposite the top edge 310a, first side edge 310c, and second side edge 310d opposite first side edge 310c. Clamp 302 includes hub 312 including first arm 314a, second arm 314b, third arm 314c, and fourth arm 314dthat respectively extend from hub 312. First arm 314a and second arm 314b respectively are configured to attach to at least a portion of the bottom edge 310b. The third arm 314c and fourth arm 314d are configured to attach to at least a portion of first side edge 310c and second side edge 310d, respectively, to allow the top edge 310a to pivot. By allowing top edge 310a to pivot, foldable display 110 can be opened into an unfolded configuration and closed into a folded configuration.

Accordingly, in some embodiments, the first portion of the foldable display apparatus includes a top edge, a bottom edge opposite the top edge, a first side edge, and a second side edge opposite the first side edge. The clamp includes a hub that includes a first arm, a second arm, a third arm, and a fourth arm that respectively extend from the hub. The first arm and the second arm respectively are configured to attach to at least a portion of the bottom edge, and the third arm and the fourth arms are configured to attach to at least a portion of the first side edge and the second side edge, respectively, to allow the top edge to pivot.

In some embodiments, the number of arms extending from the hub may be fewer or different than four arms. In one example, two arms may extend form the hub that clamp around the sides of the first portion, for example. Accordingly, in some embodiments, the clamp includes a hub that includes at least a first arm and a second arm that respectively extend from the hub; and at least the first arm and the second arm respectively are configured to attach to at least a portion of the first portion to allow a top edge of the first portion to pivot.

The example implementations of the foldable display apparatus 110 shown in FIGS. 3-8 respectively include a clamp 302.

In some embodiments, the clamp is configured to allow a top edge of the first portion to pivot.

In alternative example implementations, folding display apparatus 110 can include a metal component attached to at least a portion of the first back surface 806 and a magnet attached to articulating arm 304 configured to hold the first portion 310 and the second portion 800 of the foldable display apparatus 110 in the unfolded configuration. The metal component can be such as a steel plate, for example, or other metal to which a magnet can attach.

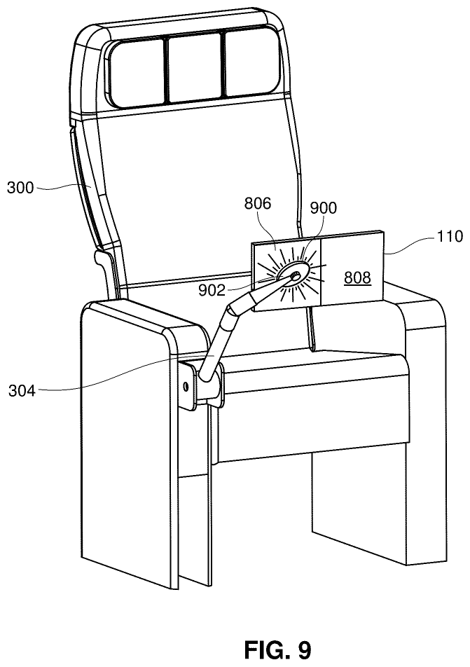

FIG. 9 illustrates an example of seat 300 and a foldable display apparatus 110 in a deployed and unfolded configuration in which a metal component 900 is attached to a portion of the first back surface 806 and a magnet 902 is attached to articulating arm 304 configured to hold the first portion 310 and the second portion 800 of the foldable display apparatus 110 in an unfolded configuration.

Accordingly, in some embodiments, the metal component 900 is attached to at least a portion of the first back surface, and the metal component is connected to a magnet 902 on the articulating arm.

Moreover, in some embodiments, the metal component 900 is connected to a magnet 902 on the articulating arm, and a connection to the articulating arm is configured to allow a top edge of the first portion to pivot.

In other embodiments, the magnet 902 is attached to at least a portion of the first back surface, and the magnet 902 is connected to a metal component 900 on the articulating arm.

Thus, in some embodiments, the magnet 902 is connected to the metal component 900 on the articulating arm, and a connection to the articulating arm is configured to allow a top edge of the first portion to pivot.

In still other example implementations, foldable display apparatus 110 can include a clamp 302, a magnet 900,902, and a metal component 902, 900. Clamp 302 can be configured to allow top edge 310a of the first portion 310 to pivot. Clamp 302 can be connected to articulating arm 304, and the magnet 900, 902 can be configured to aid in holding the first portion 310 and the second portion 800 of the foldable display apparatus 110 in the unfolded configuration.

Accordingly in some embodiments, at least one of a clamp, a magnet, and a metal component is a clamp, a magnet, and a metal component; and the clamp is configured to allow a top edge of the first portion to pivot, the clamp is connected to the articulating arm, and the magnet is configured to aid in holding the first portion and the second portion of the foldable display apparatus in the unfolded configuration. The clamp may be made out of composite and/or hard plastic such as ultem, for example. The clamp, thus, may aid in attaching the foldable display to an articulating arm of a seat back bracket via clamping or magnetic hold, for example; and also may aid moving the foldable display, e.g., by swivel, rotation, sliding, twisting, hanging, folding, etc.

In some embodiments, at least one of the clamp, the magnet, and the metal component is connected to an articulating arm mounted in an aircraft.

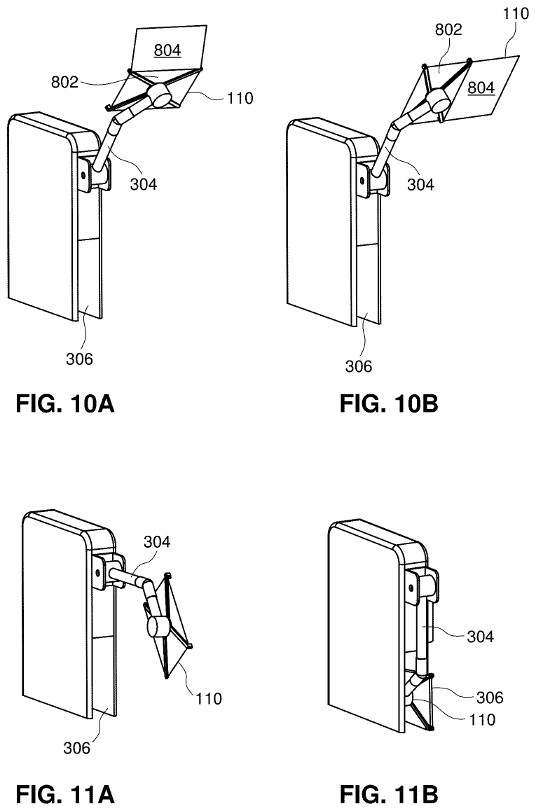

FIGS. 10A and 10B illustrate an example of movement and rotation of articulating arm 304. Articulating arm 304, in this example, is connected to structure of seat 300 in the aircraft and configured to articulate movement during deployment of foldable display apparatus 110 from video storage compartment 306.

The connection to the articulating arm 304 is configured to rotate the first portion 802 and the second portion 804 of the foldable display apparatus 110 in the unfolded configuration into a portrait orientation as shown in FIG. 10A, and a landscape orientation as shown in FIG. 10B.

Thus, in some embodiments, a connection to the articulating arm is configured to rotate the first portion and the second portion of the foldable display apparatus in the unfolded configuration into at least one of a portrait orientation and a landscape orientation.

Moreover, in some embodiments, a connection to the articulating arm is configured to rotate the first portion and the second portion to allow different viewing angles of the foldable display apparatus in the unfolded configuration.

FIGS. 11A and 11B illustrate another example of movement and rotation of articulating arm 304. Articulating arm 304, in this example, is connected to structure of seat 300 in the aircraft and configured to articulate movement during storage of the foldable display apparatus 110 to guide movement of the foldable display apparatus 110 to become aligned with and enter video storage compartment 306 within or underneath an arm of seat 300 for storage.

Accordingly, in some embodiments, the articulating arm is connected to structure of a seat in the aircraft and configured to articulate movement during storage of the foldable display apparatus to guide movement of the foldable display apparatus to become aligned with and enter a storage compartment within or underneath an arm of the seat for storage.

While video storage compartment 306 is shown in FIGS. 10A, 10B, 11A, and 11B within/underneath an arm of seat 300, the present disclosure is not so limited. For example, video storage compartment 306 may be in a space between in a recess adjacent seat 300, in a recess between a seat back 700 and a passenger, in a seat back 700, on/within a bulkhead, or on/within other structure in the aircraft.

Accordingly, in some embodiments, the foldable display apparatus in the folded configuration is configured to be stored on the aircraft in at least one of a recess in an arm of a seat, a center console, a recess adjacent a seat, a seat back, and on a bulkhead.

In some embodiments, the articulating arm is connected to a seat back in the aircraft and configured to guide rotation of the foldable display apparatus between portrait orientation and landscape orientation, and to support weight of the foldable display apparatus and guide movement in a space between the seat back and a passenger.

In other embodiments, the articulating arm is connected to a bulkhead in the aircraft and configured to guide rotation of the foldable display apparatus between portrait orientation and landscape orientation, and to support weight of the foldable display apparatus and guide movement in a space between the bulkhead and a passenger.

The foldable display apparatus of some embodiments can be much larger than video displays typically installed on many aircraft. For example, the first portion 310 and the second portion 800 of the foldable display apparatus 110 in the unfolded configuration collectively can be a display size greater than in the folded configuration, while having a size in the folded configuration that fits in video storage area on the aircraft sized for a smaller display size. This may allow for better user interactions with the foldable display apparatus despite storage size constraints.

In other words, the foldable display apparatus when collapsed or in a minimized position stows within a constrained area in the seat passenger seat or area. Yet, when the foldable display apparatus is deployed and in the unfolded configuration, the foldable display apparatus provides a larger viewing area than the size of the foldable display apparatus when stowed.

Thus, in some embodiments, the first portion and the second portion of the foldable display apparatus in the unfolded configuration collectively include a display size greater than in the folded configuration and has a size in the folded configuration that fits in a storage area on the aircraft sized for a smaller display size.

Moreover, the foldable display apparatus of embodiments of the present disclosure may provide a favorable HIC for larger seat back displays in the unfolded configuration, where the seat back display is folded and stowed during TT&L. The configuration of the foldable display apparatus provides a covered side (e.g., first back surface 806) when stowed that limits the exposure of the screen during the dynamic event, which may provide a favorable result for de-lethalization and egress in HIC testing. Additionally or alternatively, the foldable display apparatus of some embodiments of the present disclosure, e.g. for front row or center console displays connected to an arm, etc., may assist in aircrafts having close pitches such as for EY/PEY/BC seat models for example.

In another example implementation, e.g. for business class on an aircraft, the foldable display apparatus may be a foldable double sided screen that doubles as a seat PCU to actuate a seat actuation (SAC) system and when unfolded provides fight data, meals, etc. using one of the screens as an auxiliary screen.

In other example implementations, the foldable display apparatus 110 can include an additional third portion. The third portion can include a third front surface and a third back surface. The third front surface can include a third display screen. The third portion can be connected to the first portion 310 or the second portion 800 by a second joint 810 configured to allow the foldable display apparatus 110 to be moved from a folded configuration in which at least one of the first, second, and third display screens are not exposed to an unfolded configuration in which at least two of the first, second, and third display screens are exposed.

Accordingly, in some embodiments, the foldable display apparatus further includes at least one additional third portion including a third front surface and a third back surface. The third front surface includes a third display screen. The at least one third portion is connected to the first portion or the second portion by a second joint configured to allow the foldable display apparatus to be moved from a folded configuration in which at least one of the first, second, and third display screens are not exposed to an unfolded configuration in which at least two of the first, second, and third display screens are exposed.

In yet another example implementation, at least one of the first back surface 806 and the second back surface 808 includes a tray table and/or personal device holder (e.g., for a tablet, mobile phone, etc.).

Accordingly, in some embodiments, at least one of the first and second back surfaces include a tray table.

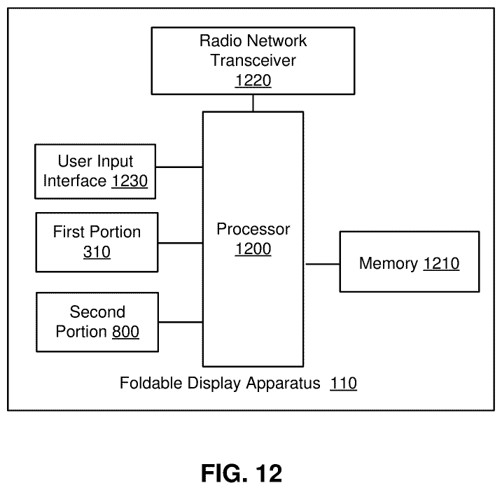

FIG. 12 is a block diagram of a foldable display apparatus 110 configured to operate according to some embodiments of the present disclosure. Referring to FIG. 12, the foldable display apparatus 110 includes a processor 1200, a memory 1210, and a radio network transceiver 1220 which can include, but is not limited to, a LTE or other cellular transceiver, WLAN transceiver (IEEE 802.11), WiMax transceiver, or other radio communication transceiver or wired network interface (e.g., Ethernet and/or USB) configured to communicate with the ground based server 190 and/or the aircraft based server 160. The foldable display apparatus 110 also includes at least two portions, for example at least a first portion 310 and a second portion 800. In some embodiments, the foldable display apparatus further includes at least one additional third portion.

The processor 1200 may include one or more data processing circuits, such as a general purpose and/or special purpose processor (e.g., microprocessor and/or digital signal processor) that may be collocated or distributed across one or more networks. The processor 1200 is configured to execute computer program code in the memory 910, described below as a non-transitory computer readable medium, to perform at least some of the operations described herein as being performed by an access control computer. The computer program code when executed by the processor 1200 causes the processor 1200 to perform operations in accordance with one or more embodiments disclosed herein for the foldable display apparatus 110. The foldable display apparatus 110 may further include a user input interface 1230 (e.g., touch screen, keyboard, keypad, etc.).

### Further Definitions and Embodiments

In the above description of various embodiments of the present disclosure, aspects of the present disclosure may be illustrated and described herein in any of a number of patentable classes or contexts including any new and useful process, machine, manufacture, or composition of matter, or any new and useful improvement thereof. Accordingly, aspects of the present disclosure may be implemented in entirely hardware, entirely software (including firmware, resident software, micro-code, etc.) or combining software and hardware implementation that may all generally be referred to herein as a “circuit,” “module,” “component,” or “system.” Furthermore, aspects of the present disclosure may take the form of a computer program product comprising one or more computer readable media having computer readable program code embodied thereon.

Any combination of one or more computer readable media may be used. The computer readable media may be a computer readable signal medium or a computer readable storage medium. A computer readable storage medium may be, for example, but not limited to, an electronic, magnetic, optical, electromagnetic, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), an appropriate optical fiber with a repeater, a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable signal medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Scala, Smalltalk, Eiffel, JADE, Emerald, C++, C#, VB.NET, Python or the like, conventional procedural programming languages, such as the “C” programming language, Visual Basic, Fortran 2003, Perl, COBOL 2002, PHP, ABAP, dynamic programming languages such as Python, Ruby and Groovy, or other programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider) or in a cloud computing environment or offered as a service such as a Software as a Service (SaaS).

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable instruction execution apparatus, create a mechanism for implementing the functions/acts specified in the flowchart and/or block diagram block or blocks.

These computer program instructions may also be stored in a computer readable medium that when executed can direct a computer, other programmable data processing apparatus, or other devices to function in a particular manner, such that the instructions when stored in the computer readable medium produce an article of manufacture including instructions which when executed, cause a computer to implement the function/act specified in the flowchart and/or block diagram block or blocks. The computer program instructions may also be loaded onto a computer, other programmable instruction execution apparatus, or other devices to cause a series of operational steps to be performed on the computer, other programmable apparatuses or other devices to produce a computer implemented process such that the instructions which execute on the computer or other programmable apparatus provide processes for implementing the functions/acts specified in the flowchart and/or block diagram block or blocks.

It is to be understood that the terminology used herein is for the purpose of describing particular embodiments only and is not intended to be limiting of the invention. Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

The flowchart and block diagrams in the figures illustrate the architecture, functionality, and operation of possible implementations of systems, methods, and computer program products according to various aspects of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular aspects only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Like reference numbers signify like elements throughout the description of the figures.

The corresponding structures, materials, acts, and equivalents of any means or step plus function elements in the claims below are intended to include any disclosed structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The aspects of the disclosure herein were chosen and described in order to best explain the principles of the disclosure and the practical application, and to enable others of ordinary skill in the art to understand the disclosure with various modifications as are suited to the particular use contemplated.

1. A foldable display apparatus configured for use with an aircraft in-flight entertainment system comprising:
a first portion comprising a first front surface and a first back surface, the first front surface comprising a first display screen;
a second portion comprising a second front surface and a second back surface, the second front surface comprising a second display screen;
the first portion and the second portion connected by a first joint configured to allow the foldable display apparatus to be moved from a folded configuration in which the first and second display screens are not exposed to an unfolded configuration in which the first and second display screens are exposed; and
at least one of a clamp, a magnet, and a metal, composite or plastic component attached to at least a portion of the first back surface and configured to hold the first portion and the second portion of the foldable display apparatus in the unfolded configuration.

2. The foldable display apparatus of claim 1, wherein the clamp comprises a hub comprising a first arm and a second arm that respectively extend from the hub, and
wherein the first arm and the second arm respectively are configured to attach to at least a portion of the first portion to allow a top edge of the first portion to pivot.

3. The foldable display apparatus of claim 1, wherein the clamp comprises a hub having two portions, the two portions comprising (i) a first hub portion comprising a first arm and a second arm that respectively extend from the first hub portion, (ii) a second hub portion comprising a third arm and a fourth arm that respectively extend from the second hub portion, and (iii) the first hub portion and the second hub portion are connected with at least one connector.

4. The foldable display apparatus of claim 1, wherein the first portion comprises a first corner, a second corner, a third corner and a fourth corner,
wherein the clamp comprises a hub and a first arm, a second arm, a third arm, and a fourth arm that respectively extend from the hub,
wherein the first arm and the second arm, respectively, comprise a first end connected to the hub and a second end configured to respectively engage (i) the first corner and a first portion of the first back surface, and (ii) the second corner and a second portion of the first back surface, and
wherein the third arm and the fourth arm, respectively, comprise a first end connected to the hub and a second end configured to respectively engage (i) a side edge of the third corner and a first portion of the first back surface, and (ii) a side edge of the fourth corner and a second portion of the first back surface.

5. The foldable display apparatus of claim 1, wherein the at least one of the clamp, the magnet, and the metal component is connected to an articulating arm mounted in an aircraft.

6. The foldable display apparatus of claim 2, wherein the hub is connected to an articulating arm mounted in an aircraft.

7. The foldable display apparatus of claim 5, wherein a connection to the articulating arm is configured to rotate the first portion and the second portion of the foldable display apparatus in the unfolded configuration into at least one of a portrait orientation and a landscape orientation.

8. The foldable display apparatus of claim 5, wherein a connection to the articulating arm is configured to rotate the first portion and the second portion to allow different viewing angles of the foldable display apparatus in the unfolded configuration.

9. The foldable display apparatus of claim 5, wherein at least one of a clamp, a magnet, and a metal component is a magnet and a metal component, and
wherein the magnet is connected to the metal component on the articulating arm, and a connection to the articulating arm is configured to allow a top edge of the first portion to pivot.

10. The foldable display apparatus of claim 5, wherein at least one of a clamp, a magnet, and a metal component is a magnet and a metal component, and
wherein the metal component is connected to a magnet on the articulating arm, and a connection to the articulating arm is configured to allow a top edge of the first portion to pivot.

11. The foldable display apparatus of claim 5, wherein at least one of a clamp, a magnet, and a metal component is a clamp, and the clamp is configured to allow a top edge of the first portion to pivot.

12. The foldable display apparatus of claim 5, wherein at least one of a clamp, a magnet, and a metal component is a clamp, a magnet, and a metal component, and
wherein the clamp is configured to allow a top edge of the first portion to pivot, the clamp is connected to the articulating arm, and the magnet is configured to aid in holding the first portion and the second portion of the foldable display apparatus in the unfolded configuration.

13. The foldable display apparatus of claim 12, wherein the magnet is attached to at least a portion of the first back surface, and the magnet is connected to a metal component on the articulating arm.

14. The foldable display apparatus of claim 12, wherein the metal component is attached to at least a portion of the first back surface, and the metal component is connected to a magnet on the articulating arm.

15. The foldable display apparatus of claim 5, wherein the articulating arm is connected to structure of a seat in the aircraft and configured to articulate movement during storage of the foldable display apparatus to guide movement of the foldable display apparatus to become aligned with and enter a storage compartment within or underneath an arm of the seat for storage.

16. The foldable display apparatus of claim 5, wherein the articulating arm is connected to a seat back in the aircraft and configured to guide rotation of the foldable display apparatus between portrait orientation and landscape orientation, and to support weight of the foldable display apparatus and guide movement in a space between the seat back and a passenger.

17. The foldable display apparatus of claim 5, wherein the articulating arm is connected to a bulkhead in the aircraft and configured to guide rotation of the foldable display apparatus between portrait orientation and landscape orientation, and to support weight of the foldable display apparatus and guide movement in a space between the bulkhead and a passenger.

18. The foldable display apparatus of claim 1, wherein the foldable display apparatus in the folded configuration is configured to be stored on the aircraft in at least one of a recess in an arm of a seat, a center console, a recess adjacent a seat, a seat back, and on a bulkhead.

19. The foldable display apparatus of claim 1, wherein the first portion and the second portion of the foldable display apparatus in the unfolded configuration collectively comprise a display size of greater than while in the folded configuration and has a size in the folded configuration that fits in a storage area on the aircraft sized for a smaller display size.

20. The foldable display apparatus of claim 1, further comprising:
at least one additional third portion comprising a third front surface and a third back surface, the third front surface comprising a third display screen,
wherein the at least one third portion is connected to the first portion or the second portion by a second joint configured to allow the foldable display apparatus to be moved from a folded configuration in which at least one of the first, second, and third display screens are not exposed to an unfolded configuration in which at least two of the first, second, and third display screens are exposed.

21. The foldable display apparatus of claim 1, wherein at least one of the first and second back surfaces comprise a tray table and/or or a personal device holder.
